(19) United States
(12) Patent Application Publication
(10) Pub. No.: US 2005/0116144 A1
(43) Pub. Date: Jun. 2, 2005

(54) Light detector with enhanced quantum efficiency

(75) Inventors: Frank Hartung, Schorndorf (DE); Jochen Paul, Aalen (DE); Harry Bauer, Aalen (DE)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(73) Assignee: Carl Zeiss SMS GmbH

(21) Appl. No.: 10/939,118

(22) Filed: Sep. 10, 2004

(30) Foreign Application Priority Data
Sep. 12, 2003 (DE) 103 42 501.2-33
Jul. 23, 2003 (DE) 103 33 712.1-51
Sep. 12, 2003 (DE) 103 42 501.2

(51) Int. Cl. H01L 31/00; H01J 40/14

(52) U.S. Cl. 250/214.1; 250/214 R

(57) ABSTRACT

A semiconductor-based, especially a silicon-based, light detector, comprising a detector body (1.1) having a detector surface (1.2) and a covering layer (2) which comprises at least one first layer (2.1) and which is arranged on the detector surface (1.2), wherein, to enhance the quantum efficiency, the covering layer (2) has a transmittance in at least one working wavelength range which is higher than the transmittance of a covering layer consisting of SiO₂ of the same thickness.

The present invention relates to a semiconductor-based, in particular a silicon-based, light detector comprising a detector body having a detector surface and a covering layer arranged on the detector surface which comprises at least one layer.

Such semiconductor-based light detectors mostly comprise so-called silicon detectors with a silicon-based detector body which is doped with a corresponding doping material. The covering layer generally consists of one or a plurality of SiO₂ (quartz) layers which act as diffusion barriers for the doping material.

Such semiconductor-based light detectors are used for numerous optical measuring applications. For example, silicon detectors are frequently used in semiconductor technology in conjunction with corresponding inspection optics for wafer inspection or the like. In this context, there is a continuous striving to enhance the sensitivity of the measuring devices used in order to achieve the best possible measurement result with a predetermined quantity of light which is limited by various factors.

In addition to corresponding changes to the inspection optics used, a possibility for increasing the sensitivity of such measuring devices consists in enhancing the quantum efficiency of the light detectors used. In this context, the quantum efficiency designates the ratio of the average number of photoelectrons produced by the light detector to the average number of photons incident in the light detector. In known light detectors, in addition to the wavelength of the light used, the quantum efficiency depends on the thickness of the SiO₂ covering layer which, among other things, reflects a certain fraction of the incident light.

One possibility for improving the quantum efficiency of such a light detector involves adapting the optical effect of the covering layer to the desired frequency band. In the range of UV light for example, the thickness of the SiO₂ covering layer must be reduced for this purpose. Narrow limits are imposed on this improvement, especially in the range of the UV light frequently used for wafer inspection. On the one hand, only a comparatively small increase in the quantum efficiency can be achieved for UV light by reducing the thickness of the SiO₂ covering layer. On the other hand, the covering layer cannot be selected to be arbitrarily thin since it then can fulfil its function as a diffusion barrier only to a limited extent and, thus, the lifetime of the light detector would be disproportionately severely reduced.

It is thus the object of the present invention to provide a light detector of the type specified initially which does not have the afore-mentioned disadvantages or at least to a lesser extent, and especially has an enhanced quantum efficiency.

The present invention solves this object starting from a light detector according to the preamble of claim 1 by the features specified in the characterising part of claim 1.

The present invention is based on the technical teaching that an enhanced quantum efficiency compared with conventional detectors is obtained in at least one working wavelength range of the light detector if, to enhance the quantum efficiency in this working wavelength range, the covering layer has a transmittance higher than the transmittance of a covering layer consisting of SiO₂ and having the same thickness. As a result of the increased transmittance compared to a covering layer consisting of SiO₂ and having the same thickness, it is advantageously achieved that more light reaches the detector surface whereby the quantum efficiency of the light detector is increased.

In other words, the increase in the transmittance can be achieved according to the invention by the covering layer having at least one layer of a corresponding material which in this working wavelength range, itself or in combination with one of a plurality of further layers, consisting of SiO₂ for example, has a transmittance higher than the transmittance of a covering layer consisting entirely of SiO₂. A comparable thickness is not required in this case.

The transmittance can be increased in various ways. On the one hand, for the working wavelength range concerned, the reflectance of the covering layer may be reduced by a layer of a suitable material. In preferred variants of the light detector according to the invention it is thus provided that the covering layer comprises at least one layer which reduces the reflectance in the working wavelength range compared to a SiO₂ covering layer. This may be achieved for example by a suitable choice of refractive index of the material used for the respective layer of the covering layer and the conditions resulting therefrom at the interfaces between the media. The smaller the difference in refractive index at the interfaces, the lower is the reflectance at the respective interface.

However, the transmittance may also be increased by reducing the absorptance of the single- or multiple-layer covering layer compared with an SiO₂ covering layer. Thus, it is preferably provided that the material or the materials for the covering layer have a lower absorptance in the working wavelength range. This may also be accomplished by a suitable choice of the material or materials for the covering layer. Preferably, in addition to reducing the absorptance, the reflectance of the covering layer is also reduced. Thus, it is preferably provided that the material of the layer which reduces the reflectance has a low absorptance in the working wavelength range.

The reflectance of the covering layer may by reduced by one or a plurality of additional layers of the covering layer, as will be described in further detail hereinafter. In embodiments of the light detector according to the invention which are advantageous because of their very simple structure, yet the first layer forms the reflectance-reducing layer. In this case, the covering layer may also consist only of the first layer of corresponding thickness.

In preferred embodiments of the light detector according to the invention with especially good reduction of the reflectance, it is provided that the material of the reflectance-reducing layer has a higher refractive index than SiO₂.

The reduction in the reflectance may be achieved by any suitable materials having the properties described. Embodiments of the light detector according to the invention with especially favourable reflectance and thus favourable transmittance are obtained if Si₃N₄ (silicon nitride) is selected as the material for the reflectance-reducing layer.

As has already been described above, multilayer covering layers may also be provided according to the invention to reduce the reflectance and therefore to increase the transmittance. In other advantageous embodiments of the light detector according to the invention the covering layer thus comprises at least one second layer which reduces the reflectance in the working wavelength range compared with an SiO₂ layer. In this case, the first layer may already bring about a corresponding increase in the transmittance. It is understood however that, with embodiments of the light detector according to the invention which are particularly simple to implement, in particular a conventional SiO₂ layer may be provided with a second layer according to the invention.

In this case again, any suitable materials for this purpose may be used for the second layer. The material of the second layer is preferably a dielectric coating material with a low absorptance in the working wavelength range. Especially suitable for the material of the second layer is one of the combinations HfO₂/SiO₂, HfO₂/MgF₂ or SiO₂/Si₃N₄.

It is again understood here that, with embodiments of the light detector according to the invention which are particularly easy to manufacture, the desired increase in the transmittance may be achieved by a single one of the second layers described previously. However, a particularly good fine tuning of the transmittance to possibly a plurality of working wavelength ranges may be achieved if a number of second layers is provided. These may be matched in terms of their dimensions to the working wavelength range or working wavelength ranges. In particular, they may be made of the same material. However, it is understood that the second layers may, additionally or alternatively, also be matched in terms of their material to the corresponding application, especially the corresponding working wavelength range or working wavelength ranges. In this case, the matching for the respective application may take place to the required parameters, such as for example spectral bandwidth, weighting of individual wavelengths etc. Thus, the material and/or the number and/or the thickness of the layers of the covering layer is preferably selected at least as a function of the first working wavelength range.

In general, the light detector may basically be optimised to one or a plurality of working wavelength ranges. In applications for wafer inspection in which the present invention may be used especially advantageously, the light detector is preferably optimised in the UV range. Thus, the first working wavelength range preferably lies in the UV range.

The present invention may be used in conjunction with light detectors based on arbitrary semiconductors. It may be used especially advantageously in conjunction with silicon detectors since its advantages are especially useful here. It is furthermore understood that the present invention may be used independently of the actual arrangement of the light detector, especially independently of the actual geometry of the respective light detector.

Further preferred embodiments of the invention become apparent from the dependent claims or the following description of preferred exemplary embodiments which also refers to the appended drawings. In the figures

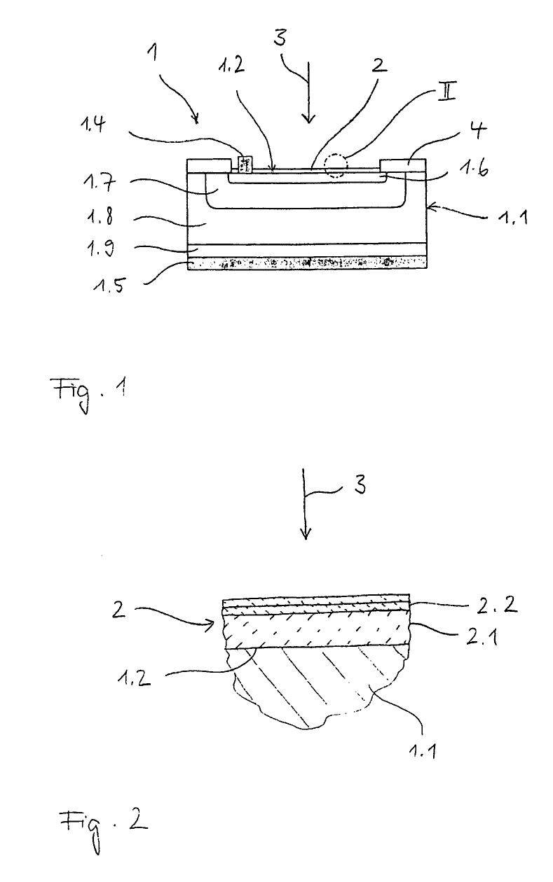

FIG. 1 is a schematic representation of a preferred embodiment of the light detector according to the invention;

FIG. 2 is a schematic sectional view of the detail II from FIG. 1;

FIG. 3 is a diagram in the context of the transmittance as a function of the thickness of the covering layer;

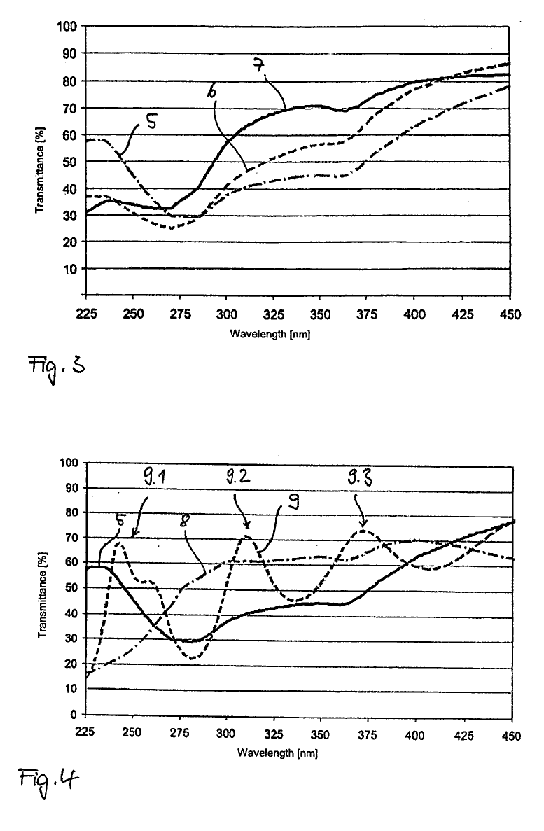

FIG. 4 is a diagram in the context of the transmittance of the design from FIG. 1 as a function of the wavelength;

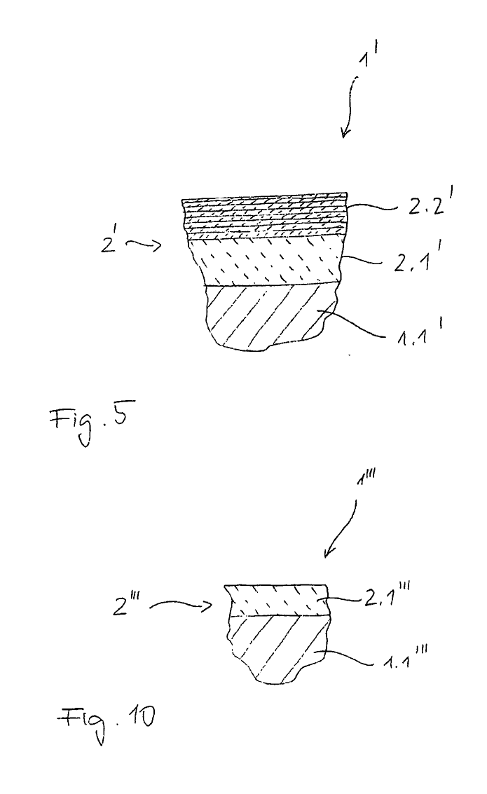

FIG. 5 is a schematic sectional view of a detail of a further embodiment of the light detector according to the invention;

FIG. 6 is a diagram in the context of the transmittance as a function of the wavelength for further embodiments of the light detector according to the invention;

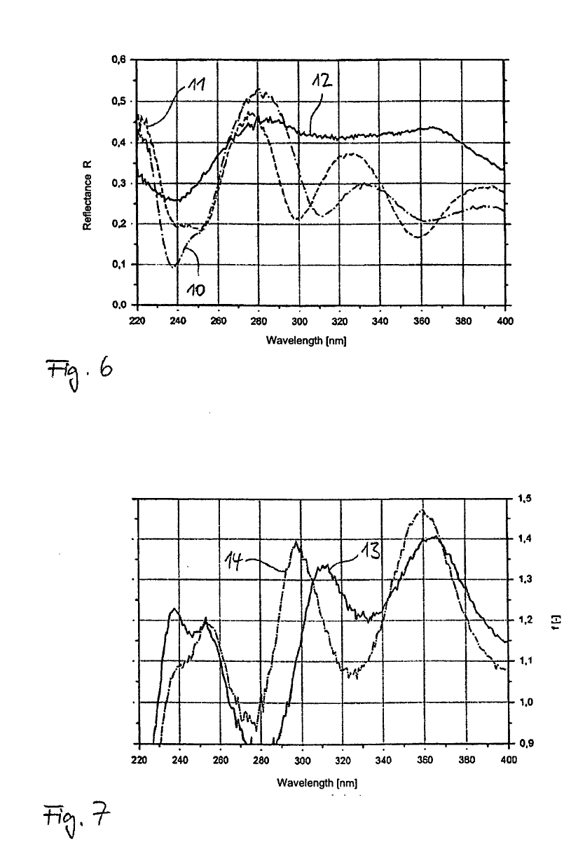

FIG. 7 is a diagram in the context of the increase in the transmittance compared with a simple SiO₂ covering layer in the embodiments of the light detector from FIG. 6;

FIG. 8 is a schematic sectional view of a detail of a further embodiment of the light detector according to the invention;

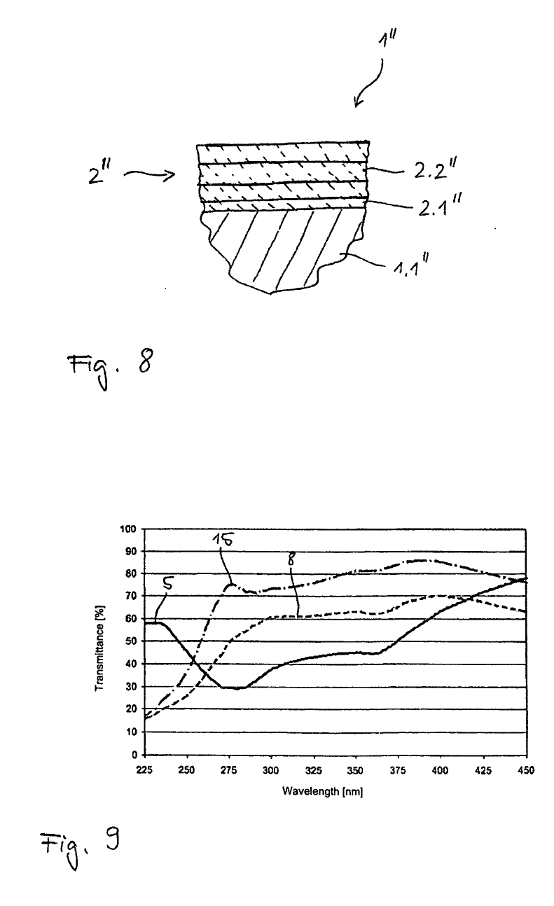

FIG. 9 is a diagram in the context of the transmittance as a function of the wavelength for the embodiment from FIG. 7;

FIG. 10 is a schematic sectional view of a detail of a further embodiment of the light detector according to the invention.

FIG. 1 shows a schematic representation of a preferred embodiment of the semiconductor-based light detector according to the invention in the form of a silicon detector 1 with a detector body 1.1 and an active detector surface 1.2 covered by a covering layer 2. The light to be detected is incident on the active detector surface 1.2 in the direction of the arrow 3.

The silicon detector 1 is otherwise constructed in the conventional fashion. Thus, it is provided with a front-side electrode 1.4 and a rear-side electrode 1.5. The detector body 1.1 comprises in the conventional fashion a p-doped zone 1.6, a depletion zone 1.7, an n-Si zone 1.8 and an n-doped zone 1.9 which adjoins the rear-side electrode 1.5. The part of the front surface not covered by the covering layer 1.3 is covered with a conventional SiO₂ protective layer 4 which serves as a diffusion barrier in this region.

The silicon detector 1 is designed for use in a first working wavelength range which lies in the UV range between 275 nm and 400 nm. As can be seen from FIG. 2, which shows the detail II from FIG. 1, the covering layer 2 acting as a diffusion barrier in the example shown comprises a first layer 2.1 of SiO₂ applied to the detector surface 1.2 and two second layers 2.2 of the same material which are arranged one above the other on the side facing away from the detector surface 1.2. The first layer 2.1 in this case has a thickness, i.e. a transverse dimension in the direction of the arrow 3, of 100 nm.

The respective second layer 2.2 consists of a material combination of HfO₂/SiO₂ which was deposited on the first layer 2.1 in a conventional fashion by vapour deposition. The material combination comprising HfO₂/SiO₂ is a UV-suitable dielectric coating material which also has a low absorptance. The low absorptance ensures a transmittance of the covering layer 2 which is as high as possible.

The respective second layer 2.2 is representing an antireflection coating which reduces the reflectance of the covering layer 3 compared with a SiO₂ layer of the same thickness and, thus, for this reason as well, increases the transmittance of the covering layer 3 compared with a SiO₂ covering layer having the same thickness, as can be seen from FIGS. 3 and 4.

FIG. 3 shows the dependence of the transmittance of an SiO₂ covering layer as a function of the thickness of the covering layer. Curve 5 gives the transmittance a SiO₂ covering layer having a thickness of 100 nm in percent as a function of the wavelength of the light used. Curve 6 gives this dependence for a SiO₂ covering layer having a thickness of 80 nm. Curve 7 shows this dependence for a SiO₂ covering layer having a thickness of 60 nm. As can be seen from these curves, over the first working wavelength range (275 nm to 400 nm) there is a clear dependence of the transmittance on the thickness of the covering layer in that the transmittance decreases with increasing thickness of the covering layer.

FIG. 4 shows a comparison between curve 5 from FIG. 3, that is the wavelength-dependent transmittance for a SiO₂ covering layer having a thickness of 100 nm, and the transmittance profiles for the covering layer 2 from FIG. 2 and for a further covering layer according to the invention. Curve 8 gives the transmittance of the covering layer 2 as a function of the wavelength of the light used, that is a covering layer with a first layer 2.1 (SiO₂) having a thickness of 100 nm and two thin second layers 2.2 (HfO₂/SiO₂). The thickness of the covering layer 2 is accordingly greater than 100 nm.

As can easily be seen from FIG. 4 with reference to curves 5 and 8, a significant increase in the transmittance compared with a pure SiO₂ covering layer having a thickness of 100 nm is achieved within the entire first working wavelength range by the additional two second layers 2.2. The thickness of the covering layer 2 is in this case greater than 100 nm so that, with the reduction in the transmittance with increasing thickness of the SiO₂ covering layer shown in connection with FIG. 3, it becomes clear that the covering layer 2 has a transmittance which is higher than the transmittance of a SiO₂ covering layer of the same thickness.

As a result of the increase in the transmittance compared with a detector having an SiO₂ covering layer of the same thickness, in the case of the silicon detector 1 an increase in the quantum efficiency compared with a detector having an SiO₂ covering layer of the same thickness is achieved accordingly.

Curve 9 from FIG. 4 gives the transmittance of the covering layer of a further preferred embodiment of the light detector 1′ according to the invention as a function of the wavelength of the light used. FIG. 5 shows a partial section of the light detector 1′. This light detector 1′ has the same general structure as the light detector 1 from FIGS. 1 and 2 so that only the differences will be discussed here.

The only difference is that, instead of the two second layers, in the silicon detector 1′, eight second layers 2.2′ of the HfO₂/SiO₂ material combination are provided which are applied to the first layer 2.1 by vapour deposition in a conventional fashion. In this embodiment, the covering layer 2′ thus consists, in other words, of a first layer 2.1′ (SiO₂) having a thickness of 100 nm and being applied to the detector body 1.1′ and eight thin second layers 2.2′ (HfO₂/SiO₂).

As can be seen from curve 9, the silicon detector 1′ is hereby optimised to three comparatively narrowly delimited working wavelength ranges in which the profile of the transmittance over the wavelength has a pronounced relative maximum in each case. These working wavelength ranges include a second working wavelength range 9.1 between 230 nm and 250 nm, a third working wavelength range 9.2 between 300 nm and 325 nm and a fourth working wavelength range 9.3 between 350 nm and 400 nm.

From this it becomes clear that the light detector according to the invention may be optimised to one or a plurality of working wavelength ranges by simply suitably varying the number of second layers. It is understood that, with other embodiments of the light detector according to the invention, in order to optimise to one or a plurality of working wavelength ranges, in addition to varying the number of layers of the covering layer, it is also possible to vary the thickness of the layers concerned. It is also understood that, additionally or alternatively, the material of the layers may also be varied in order to optimise the light detector to one or a plurality of given working wavelength ranges.

Curves 10 and 11 from FIG. 6 give the reflectance of the covering layers of further preferred embodiments of the light detector according to the invention as a function of the wavelength of the light used. These light detectors have the same general structure as those from FIGS. 1 and 2 so that only the differences will be discussed here.

The only difference is that, instead of the two second layers 2.2 in the silicon detector 1, eight second layers of the same material are deposited. In the light detector according to the invention belonging to curve 10, the second layers each consist of the material combination HfO₂/MgF₂ which was deposited by vapour deposition in a conventional fashion. In the case of the light detector according to the invention belonging to curve 11, the second layers each consist of the material combination HfO₂/SiO₂ which was also deposited in a conventional fashion by vapour deposition. Thus, the two light detectors have the same number of layers as the light detector from FIG. 5.

In comparison thereto, curve 12 from FIG. 6 shows the reflectance dependent on the wavelength of the light used in the case of a pure SiO₂ covering layer without the second layers. As can easily seen from FIG. 6, a significant reduction in the reflectance is achieved by the second layers over wide wavelength ranges. The reduction in reflection is particularly significant in the ranges around 250 nm, 300 nm and 365 nm. In addition, the second layers of HfO₂/MgF₂ and HfO₂/SiO₂ in the wavelength range over 250 nm have a low percentage absorptance so that the transmittance of the covering layer concerned and, thus, also the quantum efficiency of the respective light detector according to the invention are significantly increased compared with the detector with a pure SiO₂ covering layer (curve 12).

FIG. 7 shows the profile of an optimisation factor f as a function of the wavelength of the light used for the two light detectors according to the invention described in connection with FIG. 6. The optimisation factor f in this case is the factor by which the transmittance T by the covering layer is improved compared with the transmittance T_{SiO2} by the pure SiO₂ covering layer assuming negligible absorption losses. It thus holds that:
T=f·T_{SiO}_{₂}. (1)

The simplified optimisation factor f is calculated using the reflectance R of the covering layer of the light detector according to the invention and the reflectance R_{SiO2} of the pure SiO₂ covering layer as:

$$f = \frac{1 - R}{1 - {R}_{{SiO}_{2}}} . \qquad ( 2 )$$

Curve 13 gives the profile of the optimisation factor f for the embodiment of the light detector according to the invention described in connection with curve 10 from FIG. 6 (a first SiO₂ layer, eight second HfO₂/MgF₂ layers) whereas curve 14 shows the profile of the optimisation factor f for the embodiment described in connection with curve 11 from FIG. 5 (a first SiO₂ layer, eight second HfO₂/SiO₂ layers).

As can be seen from FIG. 7, with both embodiments, a particularly good improvement in the transmittance compared with the pure SiO₂ covering layer may be achieved in three wavelength ranges. In this case, there are certain differences with regard to the wavelengths with local maximum improvement, from which it becomes clear that, by suitably choosing the material for the respective layers, it is possible to specifically optimise with regard to certain given wavelength ranges.

FIG. 8 shows a partial cross-section through a further preferred embodiment of the light detector 1″ according to the invention. This light detector 1″ has the same general structure as the light detector 1 from FIGS. 1 and 2 so that only the differences will be discussed here.

One difference is that the first layer in the silicon detector 1″ consists of Si₃N₄ (silicon nitride) and has a thickness of 30 nm. Compared to SiO₂, Si₃N₄ has a higher refractive index, which is significantly more suitable for antireflection coating of the detector body 1.1″ of the silicon detector 1″ in the UV range. Thus, yet as a result of using Si₃N₄ for the first layer, a reduction in the reflectance and, thus, an increase in the transmittance is achieved compared with a pure SiO₂ covering layer. In other words, the first layer 2.1″ already ensures a reduction in the reflectance and, thus, an increase in the transmittance compared with a pure SiO₂ covering layer.

A further difference from the light detector from FIGS. 1 and 2 is that, instead of the two second layers, in the silicon detector 1″, three second layers 2.2″ made of the material combination SiO₂/Si₃N₄ are provided which were deposited on the first layer 2.1 by vapour deposition in a conventional fashion. A simple antireflection coating, i.e. a reduction in the reflectance compared with a pure SiO₂ covering layer, is also achieved by the second layers 2.2″.

In this embodiment, in other words, the covering layer 2″ consists of a first layer 2.1″ (Si₃N₄) having a thickness of 30 nm and being applied to the detector body 1.1″ and three second layers 2.2″ (SiO₂/Si₃N₄) with a total thickness of the second layers 2.2″ of 150 nm. An overall thickness of 180 nm is thus obtained.

FIG. 9 shows the comparison between curves 5 and 8 from FIG. 4 and a curve 15. Curve 5 gives the wavelength-dependent transmittance for a SiO₂ covering layer having a thickness of 100 nm. Curve 8 shows the wavelength-dependent transmittance for the covering layer 2 from FIG. 2 with a first SiO₂ layer having a thickness of 100 nm and two second layers of HfO₂/SiO₂. Curve 15 finally gives the wavelength-dependent transmittance of the covering layer 2″.

As can be seen from FIG. 9, for the first working wavelength range (250 nm to 400 nm), not only compared to a pure SiO₂ covering layer (curve 5) but also compared to the covering layer 2 from FIG. 2, a significant increase in the transmittance and, therefore, a significant increase in the quantum efficiency compared with these light detectors is achieved with the covering layer 2″.

A further advantage of the covering layer 2″ in addition to the increase in transmission is that, with a thickness of 180 nm, it is significantly thicker than conventional SiO₂ covering layers which are usually about 100 nm thick. The stability of the light detector and, thus, also its useful life is hereby increased.

At this point, it may be noted that, with other embodiments of the invention, for the second layers of the light detector shown in FIG. 8, it is also possible to use other coating materials. Thus, for example, SiO₂/HfO₂ may be used for the second layers wherein a wavelength-dependent profile of the transmittance is obtained which is substantially the same as curve 15.

FIG. 10 finally shows a partial section through a further preferred embodiment of the light detector 1′″ according to the invention. This light detector 1′″ has basically the same structure as the light detector 1 from FIGS. 1 and 2 so that only the differences will be discussed here.

The difference is that the covering layer 2′″ on the detector body 1.1′″ of the silicon detector 1′″ merely consists of a first layer 2.1′″ of Si₃N₄ (silicon nitride). Compared to SiO₂, Si₃N₄ has a higher refractive index, as mentioned above, which is significantly more suitable for antireflection coating of the detector body 1.1′″ of the silicon detector 1′″ in the UV range. As a result of using Si₃N₄ for the first layer, a reduction in the reflectance and therefore an increase in the transmittance is achieved compared with a pure SiO₂ covering layer. In other words, the first layer 2.1′″ alone ensures a reduction in the reflectance, and consequently an increase in the transmittance and therefore an improvement in the quantum efficiency of the light detector 1′″ compared with a light detector with a pure SiO₂ covering layer.

The present invention was described exclusively with reference to examples of silicon detectors to be optimised in the UV range. It is understood however that the invention may also be used for any other light detector based on other semiconductors. Likewise it may also be used for optimising in other wavelength ranges.

1. A semiconductor-based light detector, comprising a detector body having a detector surface and a covering layer which comprises at least one first layer and which is arranged on the detector surface, wherein, to enhance the quantum efficiency, the covering layer has a transmittance in at least one working wavelength range which is higher than the transmittance of a covering layer consisting of SiO₂ of the same thickness.

2. The light detector according to claim 1, wherein the covering layer comprises at least one layer reducing the reflectance in the at least one working wavelength range compared with a SiO₂ covering layer.

3. The light detector according to claim 2, wherein the material of the at least one layer reducing the reflectance has a low absorptance in the at least one working wavelength range.

4. The light detector according to claim 2, wherein the first layer forms the at least one layer reducing the reflectance.

5. The light detector according to claim 2, wherein the material of the at least one layer reducing the reflectance has a higher refractive index than SiO₂.

6. The light detector according to claim 2, wherein the material of the at least one layer reducing the reflectance is Si₃N₄.

7. The light detector according to claim 1, wherein the covering layer comprises at least one second layer reducing the reflectance in the at least one working wavelength range compared with a SiO₂ layer.

8. The light detector according to claim 7, wherein the material of the second layer is a dielectric coating material having a low absorptance in the at least one working wavelength range.

9. The light detector according to claim 7, wherein the material of the second layer is a material combination selected from a group consisting of the material combinations HfO₂/SiO₂, HfO₂/MgF₂ and SiO₂/Si₃N₄.

10. The light detector according to claim 7, wherein a number of second layers is provided.

11. The light detector according to claim 10, wherein the second layers are made of the same material.

12. The light detector according to claim 1, wherein at least one feature from the group consisting of the material of the layers of the covering layer, the number of layers of the covering layer and the thickness of the layers of the covering layer is selected at least depending on the at least one first working wavelength range.

13. The light detector according to claim 1, wherein the at least one working wavelength range lies in the UV range.

14. The semiconductor-based light detector according to claim 1, wherein the semiconductor is silicon.

15. A semiconductor-based light detector comprising a detector body having a detector surface and a covering layer which comprises at least one first layer and at least one second layer and which is arranged on the detector surface, wherein
the covering layer, to enhance the quantum efficiency in at least one working wavelength range, has a transmittance higher than the transmittance of a covering layer consisting of SiO₂ of the same thickness;
the material of the second layer is at least one material combination selected from a group consisting of the material combinations HfO₂/SiO₂, HfO₂/MgF₂ and SiO₂/Si₃N₄.

16. The light detector according to claim 15, wherein the covering layer comprises at least one layer reducing the reflectance in the at least one working wavelength range compared with an SiO₂ covering layer.

17. The light detector according to claim 16, wherein the material of the at least one layer reducing the reflectance has a higher refractive index than SiO₂.

18. The light detector according to claim 16, wherein the material of the at least one layer reducing the reflectance is Si₃N₄.

19. The light detector according to claim 15, wherein the at least one second layer of the covering layer reduces the reflectance in the at least one working wavelength range compared with an SiO₂ layer.

20. The light detector according to claim 15, wherein a number of second layers is provided.

21. The light detector according to claim 20, wherein the second layers are made of the same material.

22. The light detector according to claim 15, wherein at least one feature from the group consisting of the material of the layers of the covering layer, the number of layers of the covering layer and the thickness of the layers of the covering layer is selected at least depending on the at least one first working wavelength range.

23. The light detector according to claim 15, wherein the at least one working wavelength range lies in the UV range.

24. The semiconductor-based light detector according to claim 15, wherein the semiconductor is silicon.

25. A semiconductor-based light detector comprising a detector body having a detector surface and a covering layer which comprises at least one first layer and a plurality of second layers and which is arranged on the detector surface, wherein
the covering layer, to enhance the quantum efficiency in at least one working wavelength range, has a transmittance higher than the transmittance of a covering layer consisting of SiO₂ of the same thickness;
the plurality of second layers comprises a plurality of successive second layers made of the same material.

26. The light detector according to claim 25, wherein the covering layer comprises at least one layer which reduces the reflectance in the at least one working wavelength range compared with an SiO₂ covering layer.

27. The light detector according to claim 26, wherein the first layer forms at least one layer reducing the reflectance.

28. The light detector according to claim 26, wherein the material of the at least one layer reducing the reflectance has a higher refractive index than SiO₂.

29. The light detector according to claim 26, wherein the material of the at least one layer reducing the reflectance is Si₃N₄.

30. The light detector according to claim 25, wherein the plurality of second layers comprises at least one second layer reducing the reflectance in the at least one working wavelength range compared with an SiO₂ layer.

31. The light detector according to claim 30, wherein the material of the second layers is a dielectric coating material having a low absorptance in the at least one working wavelength range.

32. The light detector according to claim 30, wherein the material of the second layers is at least one material combination selected from the group consisting of the material combinations HfO₂/SiO₂, HfO₂/MgF₂ and SiO₂/Si₃N₄.

33. The light detector according to claim 25, wherein at least one feature from the group consisting of the material of the layers of the covering layer, the number of layers of the covering layer and the thickness of the layers of the covering layer is selected at least depending on the at least one first working wavelength range.

34. The light detector according to claim 25, wherein the at least one working wavelength range lies in the UV range.

35. The semiconductor-based light detector according to claim 25, wherein the semiconductor is silicon.

36. A semiconductor-based light detector comprising a detector body having a detector surface and a covering layer which comprises at least one first layer and a plurality of second layers and which is arranged on the detector surface, wherein, to enhance the quantum efficiency in at least two working wavelength ranges, the covering layer has a transmittance higher than the transmittance of a covering layer consisting of SiO₂ of the same thickness.

37. The light detector according to claim 36, wherein, to enhance the quantum efficiency in three working wavelength ranges, the covering layer has a transmittance higher than the transmittance of a covering layer consisting of SiO₂ of the same thickness.

38. The light detector according to claim 36, wherein the profile of the transmittance of the covering layer over the wavelength has a pronounced maximum in the respective working wavelength range.

39. The light detector according to claim 36, wherein the covering layer comprises at least one layer which reduces the reflectance in the at least two working wavelength ranges compared with a SiO₂ covering layer.

40. The light detector according to claim 39, wherein the material of the at least one layer reducing the reflectance has a low coefficient of absorption in the at least two working wavelength ranges.

41. The light detector according to claim 39, wherein the first layer forms the at least one layer reducing the reflectance.

42. The light detector according to claim 39, wherein the material of the at least one layer reducing the reflectance has a higher refractive index than SiO₂.

43. The light detector according to claim 39, wherein the material of the at least one layer reducing the reflectance is Si₃N₄.

44. The light detector according to claim 36, wherein the covering layer comprises at least one second layer which reduces the reflectance in the at least two working wavelength ranges compared with an SiO₂ covering layer.

45. The light detector according to claim 36, wherein the material of the second layers is a dielectric coating material having a low coefficient of absorption in the at least one working wavelength range.

46. The light detector according to claim 36, wherein the material of the second layers is at least one material combination from the group consisting of the material combinations HfO₂/SiO₂, HfO₂/MgF₂ and SiO₂/Si₃N₄.

47. The light detector according to claim 36, wherein the second layers are made of the same material.

48. The light detector according to claim 36, wherein at least one feature from the group consisting of the material of the layers of the covering layer, the number of layers of the covering layer and the thickness of the layers of the covering layer is selected at least depending on the at least one first working wavelength range.

49. The light detector according to claim 36, wherein the at least one working wavelength range lies in the UV range.

50. The semiconductor-based light detector according to claim 36, wherein the semiconductor is silicon.
